(19) United States
(12) Patent Application Publication
(10) Pub. No.: US 2003/0185740 A1
(43) Pub. Date: Oct. 2, 2003

(54) Method and apparatus for preparing aluminum nitride

(75) Inventors: Shyan-Lung Chung, Tainan (TW); Chun-Nan Lin, Changhua (TW); Jen-Chang Chen, Keelung (TW); Zheng-Xiuo Lin, Kaohsiung (TW); Jing-Yuan Liu, Ilan (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: National Cheng Kung University, Tainan (TW)

(21) Appl. No.: 10/402,434

(22) Filed: Mar. 28, 2003

Related U.S. Application Data
(62) Division of application No. 09/946,118, filed on Sep. 4, 2001.

(30) Foreign Application Priority Data
Jan. 4, 2001 (TW) 90100225

(51) Int. Cl. C01B 21/072; C23C 16/00

(52) U.S. Cl. 423/412; 118/715; 118/725

(57) ABSTRACT

A method and an apparatus for preparing aluminum nitride are disclosed. The method includes the steps of (a) providing an aluminum container, (b) providing a reactant to be received in the aluminum container, and proceeding at least one step selected from a group consisting of step (b1), step (b2) and a combination thereof, (c) placing the aluminum container into a reactor with a specific pressure and introducing nitrogen gas into the reactor, and (d) heating the reactant at a specific temperature till igniting, thereby preparing the aluminum nitride. The step (b1) is placing a layer of an aluminum nitride powder between the reactant and the aluminum container, and the step (b2) is perpendicularly placing at least one aluminum pipe into the reactant.

### FIELD OF THE INVENTION

The present invention relates to a method and an apparatus for preparing aluminum nitride (AlN), and more particularly relates a method and an apparatus for preparing high purity aluminum nitride by combustion synthesis reaction.

### BACKGROUND OF THE INVENTION

Recently, aluminum nitride (AlN) has become a very important material in industrial applications owing to its high thermal conductivity, high electrical resistivity, low thermal expansion coefficient, good thermal-shock resistance and good corrosion resistance. It has been considered for many applications, such as electronic substrates, packaging materials for integrated circuits, heat sink, high thermally conductive composite materials, and hardware for containing or processing molten metals and salts.

Presently, the methods for preparing aluminum nitride include:

1. Gas phase reaction method: e.g.

AlCl₃+4NH₃→AlN+3NH₄Cl

Referring to the gas phase reaction method for preparing aluminum nitride, the reaction temperature is 900-1500 K, the reaction time is over 5 hours, and the conversion is around 80%. Therefore, it is not suitable for mass production in industry because of the high cost and low productivity.

2. Organic metal precursor method, e.g.

R₃Al+NH₃→R₂AlNH₃

R₃AlNH₃→RAlNH₂+RH

R₂AlNH₂→RalNH+RH

RAlNH→AlN+RH

Referring to the organic metal precursor method for preparing aluminum nitride, the reaction temperature is 400-1000 K, the reaction time is 10-240 minutes and the time for removing NH₄Cl is over 5 hours. Therefore, it is also not suitable for mass production in industry because of the high cost and low productivity.

3. Carbothermal reduction method, e.g.

Al₂O₃+N₂+3C→2AlN+3CO

Referring to the carbothermal reduction method for preparing aluminum nitride, the reaction temperature is 1500-2200 K and the reaction time is over 5 hours.

4. Direct nitridation method, e.g.

2Al+N₂→2AlN

Referring to the direct nitridation method for preparing aluminum nitride, the reaction temperature is 1000-1500 K and the reaction time is over 5 hours.

5. Combustion synthesis method

The carbothermal reduction and the direct nitridation methods are the typical methods for manufacturing aluminum nitride. Both of them require a process executed under a high temperature and a long period of time, e.g., >5 hours, to fully complete the reaction, which can thus result in common disadvantages including a greater energy consumption and a slow manufacturing rate. Besides, the direct nitridation is hard to produce a high purity aluminum nitride. Furthermore, the melting and coalescence of aluminum existed during preparation increases the difficulty in the follow-up step. In addition, although aluminum nitride produced by the reduction-nitridation method has a higher purity, the reaction product contains too much carbon which requires to be removed under atmosphere. Therefore, the oxygen content of the aluminum nitride product will increase.

In comparison to other methods, the combustion synthesis method is producing aluminum nitride product by self-propagation combustion synthesis reactions. The advantages of the combustion synthesis method include a fast reaction rate, a less energy consumption and a simple manufacturing process for applying in a mass production. Referring to the combustion synthesis method for preparing aluminum nitride powder, different reactant compositions and different types of container have been disclosed as the following.

(1) A reactant used for preparing aluminum nitride by the combustion is a mixture of aluminum, aluminum nitride and other compounds such as CaCO₃, Ca(NO₃)₂, Y₂O₃, BaCO₃, Ba(NO₃)₂, Y(NO₃)₃, CeO₂ and Y₂(C₂O₄)₂ 8H₂O. Sequentially, the reactant is compressed into a particular shape, placed at nitrogen pressure of 50 atm, and heated by the electric heating strip to ignite for synthesizing aluminum nitride powder.

(2) A reactant used for preparing aluminum nitride by the combustion is a mixture of aluminum and aluminum nitride powder. Sequentially, a refractory container received the reactant is placed into liquid nitrogen and heated by the electric heating coil to ignite for synthesizing aluminum nitride powder.

(3) A reactant used for preparing aluminum nitride by the combustion is a mixture of aluminum and NaN₃ or other solid nitrogen-containing compounds such as KN₃ and Ba₃N₂. Sequentially, the reactant is put into a refractory container, an igniting agent in placed on the top of reactant, and the refractory container is put into an electric thermal furnace at a nitrogen pressure less than 10 kg/cm². After turning on the electric thermal furnace to heat the reactant, the igniting agent is heated by the electric heating coil to ignite for synthesizing aluminum nitride powder.

(4) According to U.S. Pat. No. 5,460,794, the reactant used for preparing aluminum nitride powder by the combustion is a mixture of a powdery aluminum and a solid-state nitride. Sequentially, the reactant is wrapped up with an igniting agent and the wrapped reactant is put into a stainless reactor. After evacuating the reactor and filling therein with an N₂ gas, the combustion reaction is ignited after heating power turned on for synthesizing aluminum nitride powder.

(5) According to U.S. Pat. No. 5,453,407, the reactant used for preparing aluminum nitride powder by the combustion is a mixture of a powdery aluminum, a metal azide and a salt of ammonium halide. Sequentially, the reactant is wrapped up with an igniting agent and the wrapped reactant is put into a reactor. After evacuating the reactor and filling therein with an N₂ gas, the combustion reaction is ignited after heating power turned on for synthesizing aluminum nitride powder.

(6) According to U.S. Pat. No. 5,846,508, the reactant used for preparing aluminum nitride powder by the combustion is a mixture of aluminum and ammonium halide powder. Sequentially, the reactant was molded into a tablet or poured into a refractory container having an opened end or numerous apertures is put into a reactor filled with an N₂ gas. Finally, the combustion reaction is ignited after heating power turned on for synthesizing aluminum nitride powder.

(7) A reactant used for preparing aluminum nitride powder by the combustion reaction is a mixture of aluminum and the compounds which can be melted or vaporized below the melting point of aluminum, such as NH₄X, AlCl₃, and compounds that containing NHx group (x=0, 1, 2, 3). Sequentially, the reactant was molded into a tablet or poured into a refractory container having an opened end or multiple apertures is put into a reaction vessel filled with an N₂ gas. Finally, the combustion reaction is ignited after heating power turned on for synthesizing aluminum nitride powder.

(8) According to U.S. Pat. No. 5,649,278, the reactant used for preparing aluminum nitride powder by the combustion is aluminum. The reactant is mixed with a diluent of aluminum nitride having a weight between 20-80 wt % of the total weight of the reactant and the diluent. The mixture is put into a refractory container such as a graphite crucible or an oxide ceramics, and has a packing density ranged from 0.5 to 1.5 g/cm³. Sequentially, the container is put into a reactor filled with an N₂ gas at a nitrogen pressure of 0.75-30 atm. Finally, the combustion reaction is ignited after heating power turned on for synthesizing aluminum nitride powder.

Accordingly, the combustion synthesis methods for preparing aluminum nitride powder can be divided in two groups: one is molding the reactant to a tablet such as a cylinder, and the other is pouring the reactant into a refractory container such as graphite and ceramics crucible.

In sum, the prior arts (1)-(8) have the following disadvantages. Referring to the prior art (1), the pressure of 50 atm required for synthesis of aluminum nitride could increase the cost of equipment and operation, the operation is complicated, and the operation is danger. For the prior art (2), the liquid nitrogen will cause the same problems as those of the prior art (1) even though the high-pressure condition is not required. Moreover, according to the prior arts (2), (4) and (5), when the solid-state nitrogen-containing compound is used as a nitrogen source, the solid-state nitrogen-containing compound should be easily decomposed by heat. Thus, the reaction is required a proper design such as wrapping up the reactant with the igniting agent in order to immediately proceed an reaction between aluminum powder and the nitrogen gas once the nitrogen gas is produced by the decomposition of the solid-state nitrogen-containing compounds. Otherwise, the reaction cannot be preceded because nitrogen gas escapes out rapidly.

When the ammonium halide or compound containing NHₓ group is added into aluminum powder as disclosed in the prior arts (6) and (7), a high product yield can be obtained at low nitrogen pressure. However, the side products such as HCl, NH₃, NH₄Cl, Cl₂, and, C will result in the complication and operation cost in the follow-up procedure.

In addition, when the diluent such as aluminum nitride is added to aluminum powder as described in the prior art (8), the melting and coalescence of aluminum powder can be avoided and the higher product yield will be achieved. However, owing to the high conversion is dependent on that the step of thoroughly mixing the aluminum powder with the dulent and the amount of AlN required over 30 wt %, the operation complication and cost will increase and the aluminum nitride yield for per unit volume of the reactant will decrease. Furthermore, because the packing density of the mixture of the reactant and the diluent is required between 0.5 and 1.5 g/cm³, the selection of the raw materials for the reaction is limited

Therefore, the purpose of the present invention is to develop a method and an apparatus to deal with the above situations encountered in the prior art.

### SUMMARY OF THE INVENTION

It is therefore an object of the present invention to provide a method and an apparatus for preparing aluminum nitride powder with a higher purity.

It is therefore another object of the present invention to propose a method and an apparatus for preparing aluminum nitride to easily produce aluminum nitride on a large scale.

It is therefore an additional object of the present invention to propose a method and an apparatus for preparing aluminum nitride to reduce cost because using the aluminum container.

It is therefore an additional object of the present invention to propose a method for preparing aluminum nitride to prevent aluminum powder from melting and coalescence.

It is therefore an additional object of the present invention to propose an apparatus for preparing aluminum nitride to provide sufficient nitrogen gas for completing the reaction.

According to an aspect of the present invention, there is provided a method for preparing aluminum nitride. The method includes the steps of (a) providing an aluminum container, (b) pouring a reactant into the aluminum container, and proceeding at least one step selected from a group consisting of step (b1), step (b2) and a combination thereof, (c) placing the aluminum container into a reactor and introducing nitrogen gas into the reactor, and (d) heating the reactant at a specific temperature until igniting, thereby preparing the aluminum nitride. The step (b1) is placing a layer of an aluminum nitride powder between the reactant and the aluminum container, and the step (b2) is perpendicularly placing at least one aluminum pipe into the reactant.

Preferably, the step (b) further includes a step (b3) of placing an initiator on the top surface of the reactant.

Preferably, the initiator is at least one of a diluent, an additive, an iodine (I₂), and a mixture which is capable to proceed an exothermic reaction.

Preferably, the diluent is at least one compound of aluminum nitride (AlN), boron nitride (BN), titanium nitride (TiN), silicon carbide (SiC), silicon nitride (Si₃N₄), tungsten carbide (WC), aluminum oxide (Al₂O₃), ferric chloride (FeCl₃), Zirconium dioxide (ZrO₂), titanium dioxide (TiO₂), silicon dioxide (SiO₂), carbon powder and diamond powder. Preferably, the diluent has a weight ratio of the reactant ranged from 0% to 80%.

Preferably, the additive, which will vaporize or decomposed below the melting point of aluminum, is at least one of an ammonium halide, a compound containing —NHx group and a compound containing halide.

Preferably, the mixture is Ti and C, Al and Fe₃O₄, Al and Fe, or Ni and Al. Preferably, the mixture has a weight ratio of the initiator ranged from 0.01% to 100%.

Preferably, the initiator has a thickness on the top end surface of the reactant ranged from 1 to 30 mm.

Preferably, the step (b3) further includes a step of applying a N₂ gas to pass through the reactant from the bottom to the top surface of the aluminum container.

Preferably, the layer of the aluminum nitride powder has a thickness ranged from 1 to 100 mm and has a particle size ranged from 0.01 to 10 mm.

Preferably, the aluminum pipe has a total sectional area ranged from 1 to 50% of a sectional area of the aluminum container.

Preferably, the specific pressure is ranged from 0.1 to 30 atm.

Preferably, the aluminum container has an aluminum content greater than 25 wt %.

Preferably, the reactant is an aluminum-containing material or a combination of an aluminum-containing material and a reagent. Preferably, the aluminum-containing material has a packing density ranged from 0.1 to 1.6 g/cm³. The method according to claim 15, wherein the aluminum-containing material is a pure aluminum powder having a particle size ranged from 0.01 to 200 μm. The aluminum-containing material preferably has an aluminum content greater than 25 wt % and is at least one selected from a group consisting of an pure aluminum powder, an aluminum powder comprising an aluminum alloy, and a pure aluminum alloy. Certainly, the reagent can be a diluent, an additive, an aluminum compact, two or three thereof.

Preferably, the diluent is at least one compound of aluminum nitride (AlN), boron nitride (BN), titanium nitride (TiN), silicon carbide (SiC), silicon nitride (Si₃N₄), tungsten carbide (WC), aluminum oxide (Al₂O₃), ferric chloride (FeCl₃), Zirconium dioxide (ZrO₂), titanium dioxide (TiO₂), silicon dioxide (SiO₂), carbon powder and diamond powder. Preferably, the diluent has a weight ratio of the reactant ranged from 0% to 80%.

Preferably, the additive is at least one of an ammonium halide, a compound having —NHx group and a compound having halide. The additive preferably has a weight ratio of the reactant ranged from 0% to 80%.

Preferably, the aluminum compact is composed with an aluminum foil, has a size ranged from 0.1 to 2 mm, has an aluminum content greater than 25 wt % and has an usage ranged from 0 to 30% of the reactant.

Preferably, the specific temperature is ranged from 700 to 1700° C.

Preferably, the reactor further includes a base for placing the aluminum container, and the base is made of aluminum, graphite, aluminum nitride (AlN), silicon nitride (Si₃N₄), tungsten carbide (WC), aluminum oxide (Al₂O₃), Zirconium dioxide (ZrO₂) or ceramics having high melting point.

According to another aspect of the present invention, there is provided a method for simultaneously preparing plural batches of aluminum nitride. The method includes the steps of (a) providing a plurality of aluminum containers, (b) providing a plurality of reactants to be received in the aluminum containers respectively, (c) simultaneously placing the aluminum containers into a reactor with a specific pressure and introducing nitrogen gas into the reactor, and (d) heating the reactant at a specific temperature till igniting, thereby preparing the aluminum nitride products.

According to the present invention, an apparatus is used for preparing an aluminum nitride. The apparatus includes a reactor resisted to a particular pressure, a base for placing an aluminum container and a reactant thereon, and a resistance heating device disposed on the reactant for providing an energy resource, thereby converting the reactant into the aluminum nitride.

Preferably, the reactor includes a thermocuple for measuring a reaction temperature, a nitrogen gas inlet for providing a nitrogen gas during preparing the aluminum nitride, a vacuum pump for evacuating air inside the reactor to reach a vacuum status, a pressure gauge for measuring a pressure during preparing the aluminum nitride, and a vent for recovering the pressure back to atmospheric pressure after preparing the aluminim nitride.

Preferably, the particular pressure is ranged from 0.1 to 30 atm.

According to an additional aspect of the present invention, there is provided a method for preparing aluminum nitride. The method includes the steps of (a) providing an aluminum container, (b) providing a reactant to be received in the aluminum container, (c) placing the aluminum container into a reactor with a specific pressure and introducing nitrogen gas into the reactor, and (d) heating the reactant at a specific temperature till igniting, thereby preparing the aluminum nitride.

A better understanding of the present invention can be obtained when the following detailed description of a preferred embodiment is considered in conjunction with the following drawings, in which:

### BRIEF DESCRPTION OF THE DRAWINGS

FIG. 1 is a diagram illustrating an apparatus for preparing aluminum nitride according to the present invention;

FIG. 2 is a diagram illustrating a method for preparing aluminum nitride according to a preferred embodiment of the present invention;

FIG. 3 is a diagram illustrating a method for preparing aluminum nitride according to another preferred embodiment of the present invention;

FIG. 4 is a diagram illustrating a method for simultaneously preparing plural batches of aluminum nitride according to a preferred embodiment of the present invention;

FIG. 5 is a diagram illustrating a method for simultaneously preparing plural batches of aluminum nitride according to another preferred embodiment of the present invention;

FIG. 6 is a diagram illustrating a method for preparing aluminum nitride by combustion synthesis reaction according to the present invention;

FIG. 7 is a plot illustrating an X-ray diffraction (XRD) analysis of aluminum nitride according to a preferred embodiment of the present invention;

FIG. 8 is a plot illustrating an X-ray diffraction (XRD) analysis of aluminum nitride according to another preferred embodiment of the present invention;

FIG. 9 is a plot illustrating an X-ray diffraction (XRD) analysis of aluminum nitride according to an additional preferred embodiment of the present invention;

FIG. 10 is a plot illustrating an X-ray diffraction (XRD) analysis of aluminum nitride according to an additional preferred embodiment of the present invention.

### DETAILED DESCRIPTION OF THE PREFERRED EMBODIMENTS

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

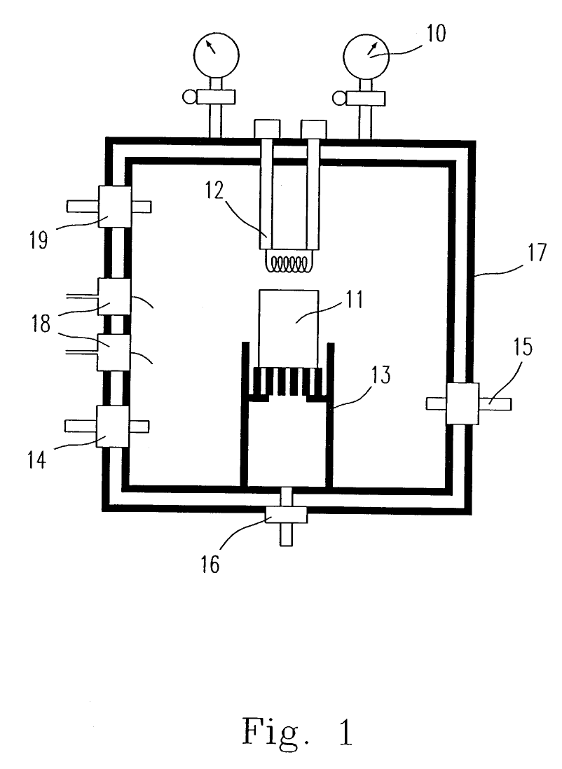

FIG. 1 is a diagram illustrating an apparatus for preparing aluminum nitride according to the present invention. The apparatus includes a reactor 17, a base 13 for placing an aluminum container 11 and a reactant thereon, and a resistance heating device 12 disposed on the reactant for providing an energy resource, thereby converting the reactant into aluminum nitride. The reactor 17 is resisted to a particular pressure ranged from 0.1 to 30 atm, and the preferred pressure for preparing aluminum nitride is ranged from 0.5 to 10 atm. The reactor 17 further includes a thermocuple 18 for measuring a reaction temperature, a nitrogen gas inlet 14, 16 for providing a nitrogen gas during preparing aluminum nitride, a vacuum tube 15 for evacuating air inside the reactor 17 to reach a vacuum status, a pressure gauge 10 for measuring a pressure during preparing aluminum nitride, and a vent 19 for recovering the pressure back to atmospheric pressure after preparing aluminum nitride.

The resistance heating device is made of a tungsten coil, a tungsten platelet, a graphite platelet, a graphite strap, a silicon carbide (SiC), a molybdenum silicide (MoSi₂), chrome-nickel coil or a tantalum (Ta) coil. In addition, the heating is performed by an electrical power, a laser, an infrared rays (IR), or a microwave. The heating temperature is ranged from 700 to 1700° C.

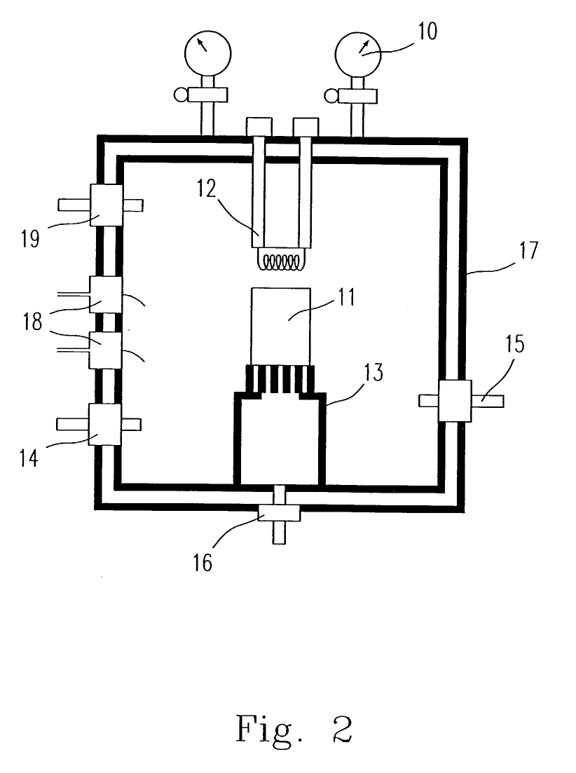

FIG. 2 is a diagram illustrating a method for preparing aluminum nitride according to a preferred embodiment of the present invention. First, a reactant is poured into an aluminum container 11, and a layer of an aluminum nitride powder is filled between the reactant and the aluminum container 11. The aluminum container 11 is placed on a base 13 which is a flat plate with apertures and inside a reactor 17. After closing the reactor 17, the nitrogen gas is introduced into the reactor 17 from the bottom via a nitrogen gas inlet 16 or from the nitrogen gas inlet 14 and the reactant is heated until igniting. Then after completing the combustion reaction, the reactant is converted into the aluminum nitride.

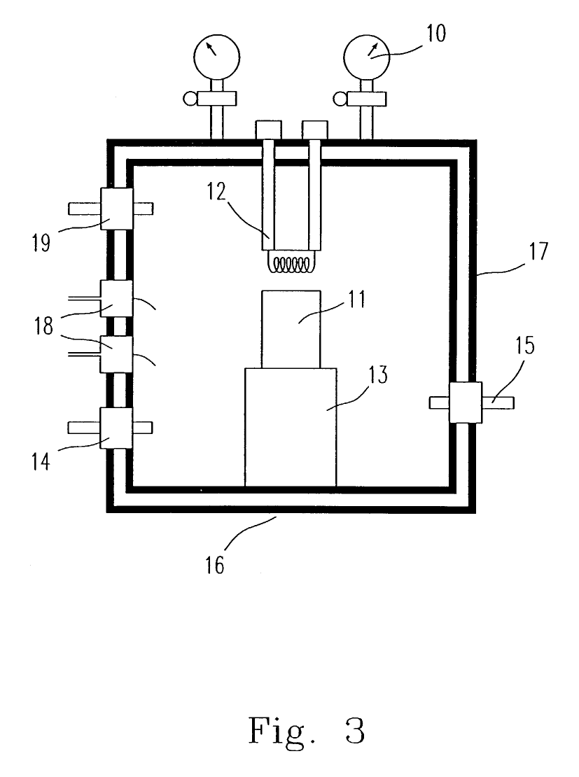

FIG. 3 is a diagram illustrating a method for preparing aluminum nitride according to a preferred embodiment of the present invention. The steps are similar to those of the above embodiment except that the base 13 is a plate without apertures, several aluminum pipes are perpendicularly placed into the reactant, and the nitrogen gas is introduced from the lateral side of the reactor 17 via the nitrogen gas inlet 14. In addition, an initiator can be placed on the top surface of the reactant for accelerating the reaction. Furthermore, the base 13 also can be a concave plate with apertures as shown in FIG. 1.

Hereinafter, the detail descriptions are given to further describe the above embodiment so as to facilitate the understanding the invention. Before preparation of aluminum nitride, an aluminum foil (33 cm×16.2 cm×0.05 cm) is wrapped around a cylinder model with an outer diameter of 100 mm and a height of 200 mm to obtain an aluminum container with two opened ends.

The aluminum container 11 is placed on the base 13 such as a graphite plate and a reactant is put into the aluminum container 11. The reactant includes an aluminum powder and an aluminum platelet. The aluminum nitride powder with an average particle size of 1 mm is accumulated on the bottom of the aluminum container 11 till 10 mm high. Sequentially, 700 g aluminum platelet with an average particle size of 40 μm and a purity of 99.7 wt % is put into the aluminum container 11. Finally, the mixture of 25 g aluminum nitride and 25 g aluminum powder is placed on the top of the aluminum platelet to be an initiator. The accumulated height of the initiator is around 5 mm.

After filling, the graphite plate with the aluminum container 11 is put into the pressure-resisted reactor 17. The resistance heating device 12, e.g. a tungsten heating coil, is placed on the top of the initiator about 4 mm and the reactor 17 is closed. Sequentially, the reactor 17 is evacuated by a vacuum pump to 0.1 torr via the vacuum tube 15, and is filled with nitrogen gas from the nitrogen gas inlets 14 or 16 to return the pressure to 1 atm. After repeating the above evacuation and nitrogen gas filling steps three times for removing the residual air in the reactor 17 and de-water treating the reactant, i.e. the aluminum platelet and the aluminum powder, 99.99 wt % nitrogen gas is filled into the reactor 17 to reach 3 atm. Sequentially, the power is turned on, so the reactant is heated at a power of 1200 W for 60 seconds to ignite and simultaneously the nitrogen gas is passed through the reactant from the bottom of the aluminum container to the top of the initiator. After igniting, the power is turned off. But the nitrogen gas is continuously passed through with a flow rate of 50 L/min, and the pressure inside the reactor is maintained at 3 atm. The reaction takes about 10 minutes for completion.

Before placing the aluminum container into the reactor, the method for preparing aluminum nitride can further include at least one of steps which is placing a layer of the aluminum nitride powder between the reactant and aluminum container, and perpendicularly placing at least one aluminum pipe into the reactant. The layer of the aluminum nitride powder has a thickness ranged from 1 to 100 mm and the preferred thickness is ranged from 3 to 50 mm. Furthermore, the particle size of the aluminum nitride powder is ranged from 0.01 to 10 mm and the preferred particle size is ranged from 0.1 to 5.0 mm. In addition, the aluminum pipe is formed by integrally forming, integrally forming an aluminum vessel and punching holes thereon, wrapping single layer of aluminum foil around an aluminum vessel and punching holes thereon, wrapping multiple layers of aluminum foils around an aluminum vessel and punching holes thereon, wrapping a aluminum pipe with single layer of aluminum foil, or wrapping a aluminum pipe with multiple layers of aluminum foil. The length of the aluminum pipe is dependent on the height of the reactant accumulation, so the optimal length of the aluminum pipe is just over the top of the reactant in the aluminum container. For preventing the aluminum pipe from squelching by the reactant and for forming the aluminum pipe to aluminum nitride during combustion, the thickness of the aluminum pipe is ranged from 0.01 to 0.5 mm and the preferred thickness is ranged from 0.05 to 0.2 mm. Moreover, the aluminum pipe has an aperture diameter ranged from 0.001 mm to 1.5 mm and the preferred aperture diameter is ranged from 0.05 mm to 1 mm. The aperture density of the aluminum pipe is around 1 to 50% and the preferred aperture density is ranged from 5 to 30%, wherein the aperture density is the ratio of the total aperture area to the total lateral surface area of the aluminum pipe. Referring to the number of the aluminum pipe used in the preparation of aluminum nitride, the total cross-sectional area of the aluminum pipe is ranged from 1 to 50% of the cross-sectional area of the aluminum container, and the preferred ratio is ranged from 5 to 20%.

The base for placing the aluminum container can be a plate with or without apertures. The shape of the plate can be flat, concave or convex. The base is made of graphite, aluminum nitride (AlN), silicon nitride (Si₃N₄), tungsten carbide (WC), aluminum oxide (Al₂O₃), Zirconium dioxide (ZrO₂) or ceramics having high melting point. The base also can be made of aluminum, which becomes aluminum nitride as combustion wave advances.

The reactant is an aluminum-containing material or a combination of the aluminum material and a reagent. The aluminum-containing material is a pure aluminum powder, an aluminum powder including aluminum alloy, a pure aluminum alloy or other admixture powder including aluminum. The other admixture powder is an aluminum powder doped with another compound, residual pieces of the pure aluminum product, or residual pieces of the aluminum alloy product. The aluminum content of the aluminum-containing material is higher than 25% and the packing density of that is ranged from 0.1 to 1.6 g/cm³. When the aluminum-containing material is the pure aluminum powder, the particle size of the pure aluminum powder is ranged from 0.01 to 200 μm.

The reagent is a dilutent, an additive, an aluminum compact or two or three thereof. The diluent has a high melting point and is a material that does not participate the reaction. The diluent is at least one of aluminum nitride (AlN), boron nitride (BN), titanium nitride (TiN), silicon carbide (SiC), silicon nitride (Si₃N₄), tungsten carbide (WC), aluminum oxide (Al₂O₃), Zirconium dioxide (ZrO₂), titanium dioxide (TiO₂), silicon dioxide (SiO₂), carbon powder and diamond powder. Furthermore, the weight ratio of the diluent to the reactant is from 0 to 80%, and the preferred ratio is ranged from 1 to 50%. When the diluent is aluminum nitride, the product is aluminum nitride. When the diluent is not aluminum nitride but other materials, the product is aluminum nitride and a composite of the aluminum nitride and other materials. The additive is a compound which can be decomposed below the melting point of aluminum, 660° C. Furthermore, the additive is at least one of an ammonium halide, a compound containing —NHx group (x=0, 1, 2, 3) and a compound containing halide. The ammonium halide compound is NH₄F, NH₄Cl, NH₄Br, or NH₄I, The compound having —NHx is CO(NH₂)₂, NH₂CO₂NH₄, (NH₄)CO₃, NH₄HF₂, KHF₂, (NH₄)₂CO₃, NH₄HCO₃, HCOONH₄, N₂H₄HCl, N₂H₄ HBr, N₂H₄,N₂H₄ 2HCl, AlCl₃, AlBr₃, or FeCl₃. The weight ratio of the additive to the reactant is from 0 to 80%, and the preferred ratio is ranged from 1 to 50%. The aluminum compact is composed with an aluminum foil and has a thickness ranged from 0.01 to 0.20 mm and the preferred thickness is ranged from 0.02 to 0.10. In addition, the size of the aluminum compact is ranged from 0.1 to 2.0 mm, the aluminum content of the aluminum compact is greater than 25 wt %, and the usage of the aluminum compact is 0 to 30% of the reactant.

The initiator is a mixture of aluminum powder and at least one of a diluent, an additive, an iodine (I₂), and a mixture which is capable to proceed a highly exothermic reaction. The respective compositions and the amounts of the diluent and the additive are the same as the diluent and the additive described above, so they will not be described repeatly. Referring to the mixture, the mixture is Ti and C, Al and Fe₃O₄, Al and Fe, or Ni and Al. The weight ratio of the mixture to the initiator is ranged from 0.01% to 100%. In addition, the thickness of the mixture on the top surface of the reactant is ranged from 1 to 30 mm.

Referring to the aluminum container, the shape of that can be cylinder, sphere, or ellipsoid. The aluminum content of the aluminum container is greater than 25 wt %. The wall of the aluminum container is integrally formed and has a structure including a single-layer with or without apertures, or a multiple-layer with or without apertures. The wall thickness of the aluminum container is ranged from 0.01 mm to 20.0 mm and the preferred wall thickness is ranged from 0.02 to 2.0 mm. In addition, the aluminum container with apertures has an aperture diameter ranged from 0.001 to 1.5 mm, and the preferred aperture diameter is ranged from 0.025 to 1.0 mm. Furthermore, the aluminum container with apertures has a ratio of the total aperture area to the total wall area ranged from 1 to 50% and the preferred ratio is ranged from 5 to 30%. The aluminum container has two-opened ends, one-opened end or the opened end sealed after putting into the reactant.

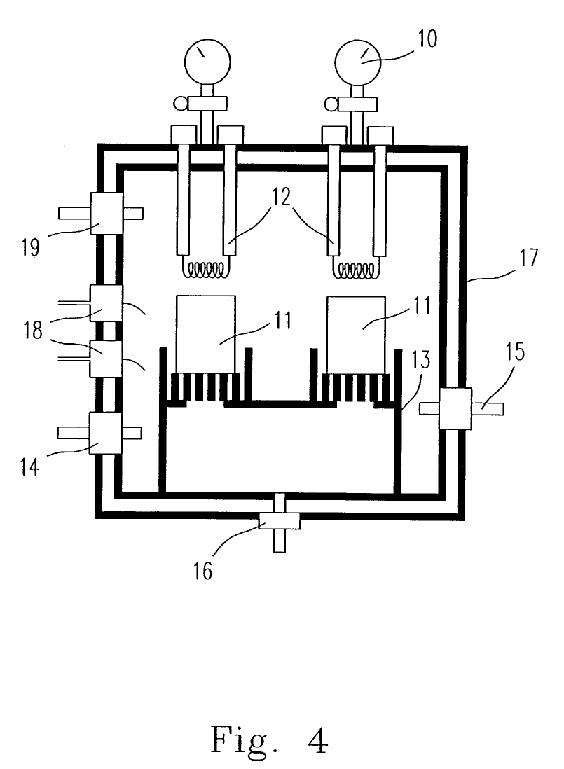

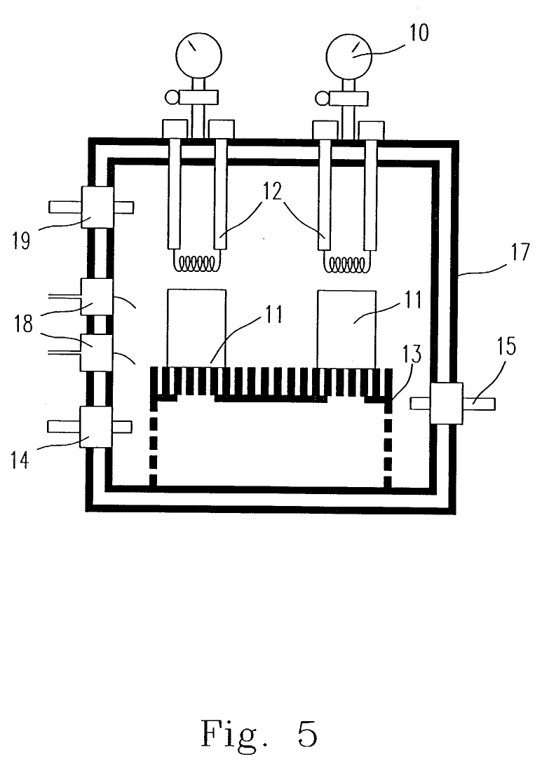

The present invention is also provides a method for simultaneously preparing plural batches of aluminum nitride as shown in FIG. 4 and FIG. 5. A plurality of aluminum containers 11 are simultaneously placed on a base 13, which is a concave plate with apertures as shown in FIG. 4 or a flat plate with apertures as shown in FIG. 5, inside the reactor 17. The procedure and principle for simultaneously preparing plural batches of aluminum nitride are similar with those for single batch of aluminum nitride. Thus, it is not required to describe repeatly.

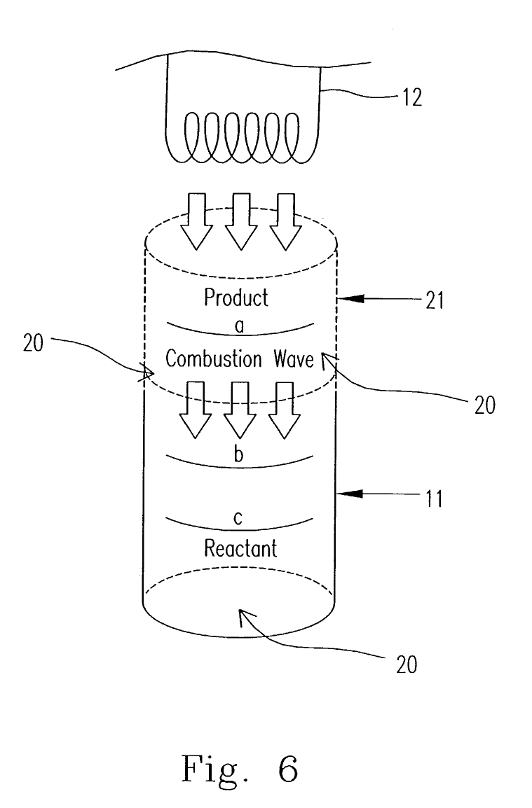

FIG. 6 is a diagram illustrating a method for preparing aluminum nitride by combustion synthesis reaction according to the present invention. When the top surface of the initiator is heated by the resistance heating device 12, the heat is transferred from the top to the bottom of the aluminum container 21, i.e. from “a” to “b” and then to “c” portions. At the same time, the nitrogen gas 20 is input into the aluminum container 21 from the bottom or the lateral side of the aluminum container 21. After igniting, the combustion wave proceeds from “a” to “c” portions, too. When the combustion wave proceeds to “a” portion, the aluminum container 21 in “a” portion will be converted to form aluminum nitride. Therefore, after completing the reaction, the whole aluminum container 21 and the reactant are converted to aluminum nitride.

The aluminum nitride prepared from the method according to the present invention is grinded to the average granule diameter of 5 μm. Approximately, 500 ml of 15 wt % HCl solution was added to 20 g of the combustion product. Thus, the amount of the residual aluminum is calculated via the volume of the hydrogen collected, and the amount of aluminum converted to aluminum nitride is further obtained. Thus, the conversion (wt %) is equal to the amount of the converted aluminum divided by the total amount of aluminum in the original materials including the reactant, the aluminum container, the aluminum nitride powder and the aluminum pipes. Furthermore, the converted product, i.e. the aluminum nitride, is determined by X-ray diffraction (XRD) analysis.

In addition, when the reactant is less than 500 g or the packing density of the reactant is smaller than 0.6 g/cm³, the addition of the diluent, the additive, or the aluminum compact does not affect the reaction. However, when the reactant is larger than 1 kg or the packing density of the reactant is larger than 0.8 g/cm³, the addition of the diluent, the additive, or the aluminum compact shows significant effect on the reaction.

Embodiment 1: Using Pure Aluminum as the Reactant

When preparing aluminum nitride according to the present invention, pure aluminum powder or platelet is used as the reactant and the combustion synthesis reaction is proceed at different pressures, different packing densities and different types of container. The results are shown in Table 1.

As shown in Table 1, the reactant is pure aluminum (platelet, D₅₀=˜40 μm, thickness=0.1 μm, 99% purity, 0.5% oxygen content) in experiments 1-8, but the aluminum nitride powder is filled between the reactant and the aluminum container or the aluminum pipes are put into the reactant in experiments 6-8. The aluminum container is cylinder and one opened end, and the wall of the aluminum container has a thickness of 0.0254 mm.

TABLE 1
The combustion synthesis reaction results by using pure aluminum as the
reactant at different conditions.

| | Al container type: | | | | |
|---|---|---|---|---|---|
| | w/ or w/o aper- | Reactant: | | | |
| | tures; aperture | Weight (g); | Nitrogen | AlN | |
| Exp. | diameter (mm); | Packing density | pressure | yield | |
| No. | aperture area (%) | (g/cm³) | (atm) | (%) | Color |
| 1 | with apertures, | 50 g | 2 | 91 | gray- |
| | 0.05-0.5 mm, | 0.55 g/cm³ | | | brown & |
| | 30% | | | | white |
| 2 | without aperture | 100 g | 3 | 90 | gray- |
| | | 0.55 g/cm³ | | | brown & |
| | | | | | white |
| 3 | with apertures, | 100 g | 3 | 92 | gray- |
| | 0.1-1.0 mm, | 0.55 g/cm³ | | | brown & |
| | 30% | | | | white |
| 4 | with apertures, | 100 g | 3 | 68 | black- |
| | 0.1-1.0 mm, | 0.82 g/cm³ | | | gray |
| | 50% | | | | |
| 5 | without aperture | 100 g | 5 | 80 | black- |
| | | 0.92 g/cm³ | | | gray |
| 6 | without aperture | 100 g | 3 | 98 | Orange |
| | * AlN powder | 0.55 g/cm³ | | | |
| 7 | with apertures, | 200 g | 3 | 98.2 | Orange |
| | 0.1-1.0 mm, | 0.55 g/cm³ | | | |
| | 30%, | | | | |
| | ** Al pipes | | | | |
| 8 | with apertures, | 200 g | 3 | 99 | Orange |
| | 0.1-2.0 mm, | 0.55 g/cm³ | | | |
| | 30%, | | | | |
| | *** AlN | | | | |
| | powder + Al | | | | |
| | pipes | | | | |

* 3 mm thickness of AlN powder is filled between the reactant and the Al container.
** The Al pipes are put into the reactant.
*** 3 mm thickness of AlN powder is filled between the reactant and the Al container and the Al pipes are put into the reactant.

For the experiments 1-8, the heating power is 1800 W, the heating time is 60-100 seconds, and the reaction time is 3-6 minutes. As shown in Table 1, the larger the nitrogen pressure is or the smaller the packing density is, the shorter the reaction time is. Furthermore, the oxygen contents of the aluminum nitride products are around 0.8 to 0.9 wt %. After grinding, the aluminum nitride products prepared from experiments 1-5 are determined by X-ray diffraction (XRD) analysis and a trace amount of residual aluminum is detected (not shown).

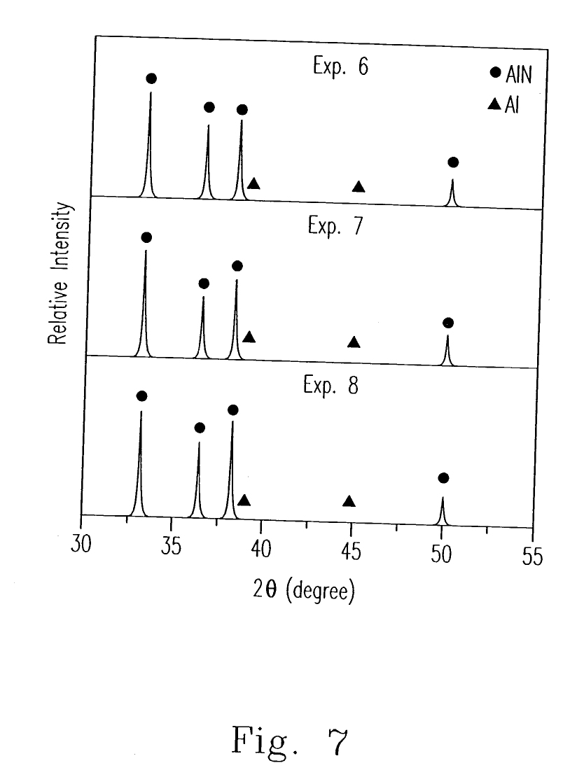

In addition, in the experiment 6, a layer of the AlN powder having a thickness of 3 mm is filled between the reactant and the aluminum container. The granule diameter distribution of the AlN powder is ranged from 0.5 to 1.0 mm. In the experiment 7, aluminum pipes having a wall thickness of 0.025 mm, a diameter of 5 mm, an aperture diameter of 0.05˜1.00 mm and a aperture area of 50%, are put into the reactant. The those of the experiment 7 except a layer of the AlN powder having a thickness of 3 mm is simultaneously filled between the reactant and the aluminum container. The aluminum nitride products prepared from the experiments 6-8 are grinded and determined by XRD analysis. As shown in FIG. 7, the results show that the products are all aluminum nitride and no residual aluminum is detected.

Embodiment 2: Using Pure Aluminum as the Reactant and Applying Nitrogen Gas from the Bottom of the Aluminum Container

When preparing aluminum nitride according to the present invention, pure aluminum powder or platelet is used as the reactant and the nitrogen gas is applied from the bottom of the aluminum container during combustion synthesis reaction. The results are shown in Table 2.

TABLE 2
The combustion synthesis reaction results by using pure aluminum as the
reactant and applying the nitrogen gas from the bottom of the Al container
at different conditions.

| | Al container type | | | | |
|---|---|---|---|---|---|
| | & size: w/ or w/o | | | | |
| | apertures; Wall | Shapes of | Reactant: | | |
| | thickness (mm) | the plate | Weight (g); | Nitrogen | AlN |
| Exp. | Diameter (cm); | with | Packing density | pressure | yield |
| No. | Height (cm) | apertures | (g/cm³) | (atm) | (%) |
| 9 | with apertures, | Flat | 700 g | 2 | 99.2 |
| | 0.03 mm, | | 0.53 g/cm³ | 50 L/min | |
| | D: 10 cm, | | | | |
| | H: 13 cm | | | | |
| 10 | Without aperture | Concave | 400 g | 2 | 99.2 |
| | 0.06 mm, | | 0.60 g/cm³ | 30 L/min | |
| | D: 10 cm, | | | | |
| | H: 14 cm | | | | |
| 11 | with apertures, | Convex | 400 g | 3 | 99.4 |
| | 0.10 mm, | | 0.60 g/cm³ | 5 L/min | |
| | D: 10 cm, | | | | |
| | H: 14 cm | | | | |

In experiments 9-11, the aluminum container is cylinder and the size of that is shown in Table 2. In addition, the aluminum container used in the experiments 9 and 10 is one opened end and the other closed end with apertures whereas that used in the experiment 11 is two opened ends. Furthermore, in the experiment 11, the aluminum pipe is put into the reactant. The characteristics of the aluminum pipe are the same as those described in the experiment 7.

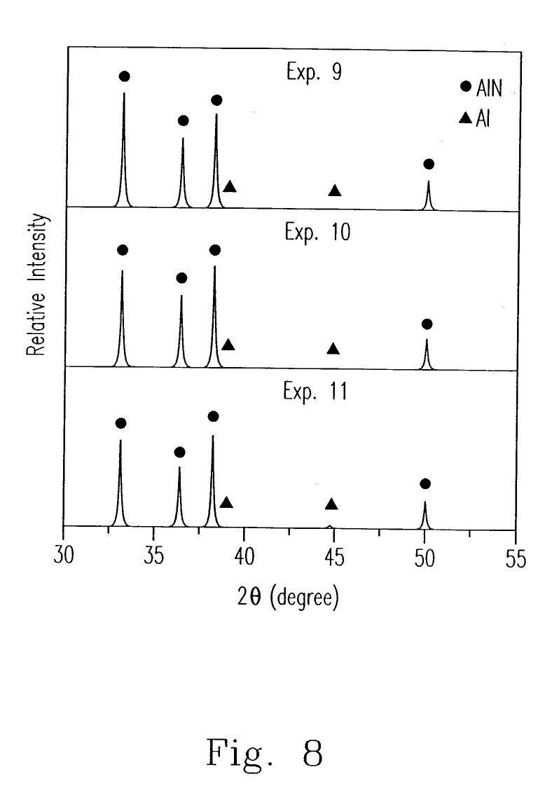

For the experiments 9-10, the heating power is 2000 W, the heating time is 60-100 seconds, and the reaction time is 10-15 minutes. The major color of the reaction product is orange and little white appears around the reaction product. In addition, the reaction products prepared from the experiments 9-11 are grinded and determined by XRD analysis. As shown in FIG. 8, the results show that the products are all aluminum nitride and no residual aluminum is detected. Furthermore, the oxygen content of the reaction product is around 0.7˜0.8 wt %.

Embodiment 3: Using Pure Aluminum and Different Diluents as the Reactant

When preparing aluminum nitride according to the present invention, pure aluminum powder or platelet and different diluents are used as the reactant and the combustion synthesis reaction is proceed at different pressures and different packing densities. The results are shown in Table 3.

The aluminum container used in the experiments 12-17 has no aperture thereon and the wall thickness is 0.05 mm. The nitrogen gas is applied from the bottom of the aluminum container in the experiments 13 and 15-17 but not in the experiments 12, 14 and 18-19. Furthermore, the aperture plate used in the experiments 13 and 15-17 is the same as that used in the experiment 10. In addition, the granule diameter distribution of the diluents as shown in Table 3 are respectively as the following: AlN is 0.1-2.0 mm; Al₂O₃ is 0.01-0.5 mm; D₅₀ of SiC is ˜2 μm; D₅₀ Si₃N₄ is ˜3 μm.

TABLE 3
The combustion synthesis reaction results by using pure aluminum and
different diluents as the reactant at different conditions.

| | | Reactant: | N₂ | | | |
|---|---|---|---|---|---|---|
| | | Weight (g); | pressure | | | |
| | Reactant | Packing | (atm) & | | Oxygen | AlN |
| Exp. | composition | density | flow rate | | content | yield |
| No. | (wt %) | (g/cm³) | (L/min) | Color | (wt %) | (%) |
| 12 | 50% Al + | 100 g | 3 atm | yellow- | 1.2 | 99.1 |
| | 50% AlN | 0.71 g/cm³ | 0 L/min | white | | |
| 13 | 75% Al + | 600 g | 2 atm | yellow- | 1.0 | 99.3 |
| | 25% AlN | 0.56 g/cm³ | 50 L/min | white | | |
| 14 | 40% Al + | 100 g | 3 atm | white | 21.3 | 98.9 |
| | 60% Al₂O₃ | 0.82 g/cm³ | 0 L/min | | | |
| 15 | 50% Al + | 700 g | 2 atm | white | 19.1 | 99.2 |
| | 50% Al₂O₃ | 0.85 g/cm³ | 80 L/min | | | |
| 16 | 90% Al + | 500 g | 3 atm | yellow- | 0.8 | 99.1 |
| | 10% SiC | 0.58 g/cm³ | 60 L/min | black | | |
| 17 | 30% Al + | 600 g | 2 atm | white | 1.1 | 98.6 |
| | 70% Si₃N₄ | 0.92 g/cm³ | 60 L/min | | | |
| 18 | 60% Al + | 500 g | 4 atm | yellow- | 1.0 | 98.5 |
| | 40% AlN | 0.82 g/cm³ | 0 L/min | white | | |
| 19 | 70% Al + | 400 g | 3 atm | yellow- | 0.9 | 98.7 |
| | 30% AlN | 0.75 g/cm³ | 0 L/min | white | | |

The aluminum pipe is used in the experiment 18 as that in the experiment 7, and the aluminum nitride layer and the aluminum pipe are used the experiment 19 as those in the experiment 18.

For the experiments 12-19, the heating power is 1200 W and the heating time is 20-40 seconds. As shown in Table 3, the higher the diluent amount is, the shorter the heating time is required.

The reaction products prepared from the experiments 12-19 are grinded and determined by X-ray diffraction analysis. The results indicate that the reaction products are aluminum nitride or the complex containing aluminum nitride, and no residual aluminum is detected (not shown).

In addition, if the aluminum pipe or the aluminum nitride layer is not applied in the experiments 18 and 19, the reaction products are gray-white or light brown color and the conversions are only 95%.

Embodiment 4: Using Pure Aluminum and Different Additives as the Reactant

When preparing aluminum nitride according to the present invention, pure aluminum powder or platelet and different additives are used as the reactant and the combustion synthesis reaction is proceed at different pressure and different packing densities. The results are shown in Table 4.

The reaction conditions in the experiments 20-23 are similar with those in the experiment 10 and the different conditions therebetween are shown in Table 4. In addition, the aluminum nitride layer is used in the experiment 24 as that in the experiment 6 and the aluminum pipe is used in the experiment 25 as that in the experiment 7.

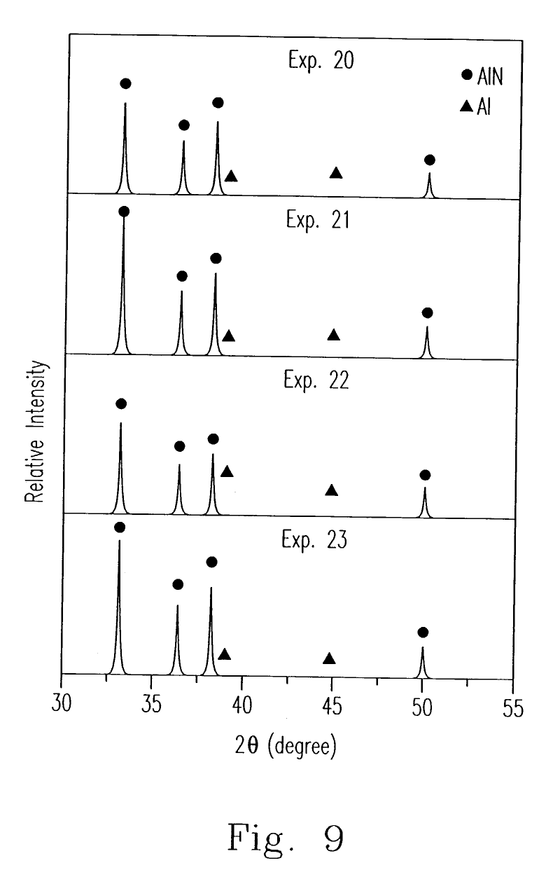

For the experiments 20-25, the heating power is 1200 W, the heating time is 10-20 seconds, and the reaction time is 5-10 minutes. The reaction prepared from experiments 20-25 are determined by X-ray diffraction analysis. As shown in FIG. 9, the results show that the reaction products prepared from the experiments 20-23 are only aluminum nitride and no residual aluminum is detected (not shown).

TABLE 4
The combustion synthesis reaction results by using pure aluminum and
different additives as the reactant at different conditions.

| | | Reactant: | | |
|---|---|---|---|---|
| | | Weight (g); | | |
| | Reactant | Packing | N₂ pressure | |
| Exp. | composition | density | (atm) & flow | Conversion |
| No. | (wt %) | (g/cm³) | rate (L/min) | (%) |
| 20 | 99.5% Al + | 600 g | 2 atm | 99.5 |
| | 0.5% NH₄Cl % | 0.63 g/cm³ | 50 L/min | |
| 21 | 99% Al + | 500 g | 3 atm | 99.3 |
| | 1% AlCl₃ | 0.6 g/cm³ | 80 L/min | |
| 22 | 99% Al + | 700 g | 2 atm | 99 |
| | 1% FeCl₃ | 0.65 g/cm³ | 100 L/min | |
| 23 | 95% Al + | 500 g | 3 atm | 98.7 |
| | 5% CO(NH₂)₂ | 0.6 g/cm³ | 70 L/min | |
| 24 | 99% Al + | 100 g | 3 atm | 99.2 |
| | 1% NH₄Cl | 0.53 g/cm³ | 0 L/min | |
| 25 | 99.5% Al + | 500 g | 3 atm | 98.9 |
| | 0.5% NH₄Cl | 0.6 g/cm³ | 0 L/min | |

In addition, if the aluminum pipe or the aluminum nitride layer is not applied in the experiments 24 and 25, the residual aluminum in the reaction products will be detected and the conversions are 96.2% and 95.0% respectively.

Embodiment 5: Using Pure Aluminum and Aluminum Compact as the Reactant

When preparing aluminum nitride according to the present invention, pure aluminum powder or platelet and the aluminum compact are used as the reactant and the combustion synthesis reaction is proceed at different pressures and different packing densities. The results are shown Table 5.

TABLE 5
The combustion synthesis reaction results by using pure aluminum and
aluminum compact as the reactant at different conditions.

| | | Reactant: | | | |
|---|---|---|---|---|---|
| | Reactant | Weight (g); | N₂ pressure | Oxygen | Con- |
| Exp. | composition | Packing density | (atm) & flow | content | version |
| No. | (wt %) | (g/cm³) | rate (L/min) | (%) | (%) |
| 26 | 95% Al + | 300 g | 2 atm | 0.7 | 99.5 |
| | 5% Al compact | 0.53 g/cm³ | 40 L/min | | |
| 27 | 95% Al + | 300 g | 3 atm | 0.9 | 99.2 |
| | 5% Al compact | 0.9 g/cm³ | 60 L/min | | |
| 28 | 90% Al + 10% | 300 g | 3 atm | 0.6 | 99.4 |
| | Al compact | 0.9 g/cm³ | 100 L/min | | |

The reaction conditions in the experiments 26-28 are similar with those in the experiment 9 and the different conditions and results therebetween are shown in Table 5. In addition, the aluminum compact used in the experiments 26-28 is the aluminum foil strip (40 mm×0.02 mm) forming a non-compacted and irregular-shaped cluster with a size of 0.1˜2.0 mm.

For the experiments 26-28, the heating power is 2000 W and the heating time is 60-100 seconds. The reaction prepared from experiments 20-25 are all yellow-brown color and determined by X-ray diffraction analysis. The results indicate that the reaction products prepared from the experiments 26-28 are only aluminum nitride and no residual aluminum is detected (not shown).

In addition, if the nitrogen gas is not applied from the bottom of the aluminum container in the experiments 26-28, the reaction products is gray-brown color and the conversions are 95.7%, 89.2% and 90.7% respectively. However, the residual aluminum is also not detected from the above reaction products.

Embodiment 6: Using Pure Aluminum as the Reactant and Adding the Initiator

When preparing aluminum nitride according to the present invention, pure aluminum powder or platelet is used as the reactant, the initiator is added, and the combustion synthesis reaction is proceed at different pressure and different packing densities. The results are shown in Table 6.

The reaction conditions in the experiments 29-34 are similar with those in the experiment 9 and the different conditions and results therebetween are shown in Table 6. In addition, the purity and oxygen content of aluminum powder used in the experiments 33 and 34 are 99.0 wt % and 0.5 wt %, and 99.7 wt % and 0.1 wt %, respectively.

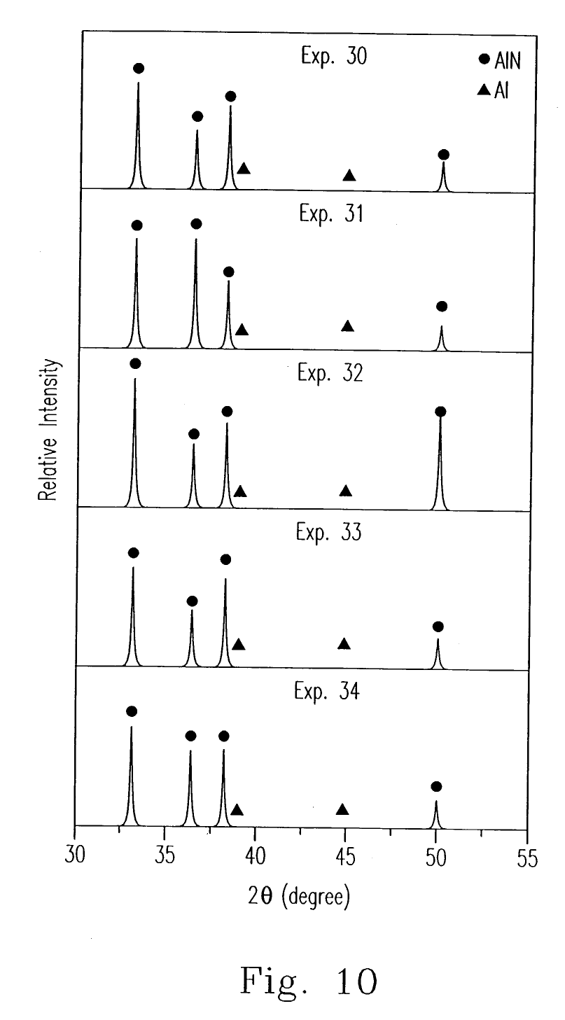

For the experiments 29-34, the heating power is 1200 W and the heating time is 10-20 seconds. The reaction products prepared from experiments 29-34 are grinded and determined by X-ray diffraction analysis. The results indicate that the reaction products prepared from the experiments 29-34 are only aluminum nitride and no residual aluminum is detected. The XRD results of the experiments 30-34 are shown in FIG. 10.

TABLE 6
The combustion synthesis reaction results by using pure aluminum as the
reactant and adding the different initiators at different conditions.

| | | | | N₂ | | |
|---|---|---|---|---|---|---|
| | Reactant | | Reactant: | pressure | | |
| | compo- | Thickness | Weight (g); | (atm) & | Oxygen | |
| Exp. | sition | of initiator | Packing density | flow rate | content | Conversion |
| No. | (wt %) | (mm) | (g/cm³) | (L/min) | (%) | (%) |
| 29 | 50% Al + | 5 mm | 600 g | 2 atm | 0.53 | 99.5 |
| | 50% AlN | | 0.63 g/cm³ | 40 L/min | | |
| 30 | 99% Al + | 3 mm | 500 g | 3 atm | 0.67 | 99.4 |
| | 1% NH₄Cl | | 0.6 g/cm³ | 60 L/min | | |
| 31 | 99.5% Al + | 2 mm | 700 g | 2 atm | 0.79 | 98.8 |
| | 0.5% FeCl₃ | | 0.65 g/cm³ | 100 L/min | | |
| 32 | 99% Al + | 6 mm | 500 g | 3 atm | 0.62 | 99.2 |
| | 1% I₂ | | 0.6 g/cm³ | 70 L/min | | |
| 33 | 50% Ti + | 3 mm | 100 g | 4 atm | 0.81 | 99.3 |
| | 50% C | | 0.53 g/cm³ | 50 L/min | | |
| 34 | 50% Al + | 5 mm | 750 g | 3 atm | 0.53 | 98.9 |
| | 50% AlN | | 0.53 g/cm³ | 50 L/min | | |

Embodiment 7: Using Pure Aluminum as the Reactant, Applying the Aluminum Pipe or the Aluminum Compact, and Adding the Initiator

When preparing aluminum nitride according to the present invention, pure aluminum powder or platelet is used as the reactant, the aluminum pipe or the aluminum compact is used, the initiator is added and the combustion synthesis reaction is proceed at different pressure. The results are shown in Table 7.

The reaction conditions in the experiments 35 and 36 are similar with those in the experiments 7 and 26, respectively.

For the experiments 35 and 36, the heating power is 1200 W and the heating time is 10-20 seconds. The reaction products prepared from experiments 35 and 36 are grinded and determined by X-ray diffraction analysis. The results indicate that the reaction products prepared from the experiments 35 and 36 are only aluminum nitride and no residual aluminum is detected.

TABLE 7
The combustion synthesis reaction results by using pure aluminum as the
reactant and the different initiators at different conditions.

| | | Thick- | | N₂ | | |
|---|---|---|---|---|---|---|
| | | ness | | pressure | | |
| | | of | | (atm) & | Oxygen | Con- |
| Exp. | Initiator | initiator | Reactant | flow rate | content | version |
| No. | composition | (mm) | weight (g) | (L/min) | (%) | (%) |
| 35 | Al + Fe₃O₄ | 3 mm | 200 g | 3 atm | 1.1 | 98.9 |
| | | | | 0 L/min | | |
| 36 | Al + Ni | 5 mm | 200 g | 3 atm | 0.7 | 98.5 |
| | | | | 0 L/min | | |

In addition, if the aluminum pipe or the aluminum compact is not applied in the experiments 35 and 36, the residual aluminum in the reaction products will be detected and the conversions are 96.7% and 96.1% respectively.

Embodiment 8: Using Different Sources and Compositions of Aluminum Powder as the Reactant

When preparing aluminum nitride according to the present invention, different sources and compositions of the aluminum powder or platelet are used as the reactant and the combustion synthesis reaction is proceed at different pressure and different packing densities. The results are shown in Table 8.

TABLE 8
The combustion synthesis reaction results by using different sources and
compositions of aluminum powder as the reactant at different conditions.

| | | | N₂ | |
|---|---|---|---|---|
| | | Weight (g) | pressure | |
| | | & Packing | (atm) & | Composition |
| Exp. | Composition of | density | flow rate | of reaction |
| No. | Al-containing powder | (g/cm³) | (L/min) | product |
| 37 | residual pieces of Al | 300 g | 2 atm | AlN, Mg, Mn, |
| | alloy product | 0.7 g/cm³ | 100 L/min | Fe, Si |
| | (92% Al, 1% Fe, 6% | | | |
| | Mg, 0.7% Si, | | | |
| | 0.3% Mn) | | | |
| 38 | Al powder + the | 300 | 3 atm | AlN, Fe, C, |
| | mixture (85% Al, | 0.6 g/cm³ | 80 L/min | Si₃N₄, Si, |
| | 7% Ti, 3% C, 3% Fe, | | | FeAlₓ, TiC, |
| | 2% Si) | | | TiN |

Embodiment 9: Using Different Reactant Compositions and Simultaneously Placing Four Aluminum Containers in the Reactor

When preparing aluminum nitride according to the present invention, different reactant compositions are used, four aluminum containers are simultaneously placed in the reactor and the combustion synthesis reaction is proceed without applying the nitrogen gas from the bottom of the aluminum containers at different pressure. The results are shown in Table 9.

The reaction conditions in the experiments 39 and 40 are similar with those in the experiments 25 and 19, respectively, except four aluminum containers are simultaneously placing in the reactor.

The four reactants in the experiment 39 are simultaneously heated and ignited while the four reactants in the experiment 40 are ignited one by one. The reaction products prepared from experiments 39 and 40 are grinded and determined by X-ray diffraction analysis. The results indicate that the reaction products prepared from the experiments 39 and 40 are only aluminum nitride and no residual aluminum is detected (not shown).

TABLE 9
The combustion synthesis reaction results by using different reactant
compositions and simultaneously preparing four batches of the reaction
product without applying the nitrogen gas from the bottom of the
aluminum containers at different conditions.

| | Reactant | Reactant weight (g) & | | Con- |
|---|---|---|---|---|
| Exp. | composition | Packing density (g/cm³) | N₂ pressure | version |
| No. | (wt %) | for each Al container | (atm) | (%) |
| 39 | 99.5% Al + | 500 g | 3 atm | 99% |
| | 0.5% NH₄Cl | 0.6 g/cm³ | | |
| 40 | 40% Al + | 400 g | 4 atm | 98.8% |
| | 60% AlN | 0.8 g/cm³ | | |

Embodiment 10: Simultaneously Placing Plural Aluminum Containers in the Reactor and Applying the Nitrogen Gas from the Bottom of the Aluminum Containers

When preparing aluminum nitride according to the present invention, different reactant compositions are used, plural aluminum containers are simultaneously placed in the reactor and the combustion synthesis reaction is proceed with applying the nitrogen gas from the bottom of the aluminum containers at different pressures. The results are shown in Table 10.

The reaction conditions in the experiments 41 and 42 are similar with those in the experiments 29 and 30, respectively, except nine aluminum containers are simultaneously placing in the reactor.

The nine reactants in the experiment 41 are simultaneously heated and ignited while the nine reactants in the experiment 42 are ignited one by one. The reaction products prepared from experiments 41 and 42 are grinded and determined by X-ray diffraction analysis. The results indicate that the reaction products prepared from the experiments 41 and 42 are only aluminum nitride and no residual aluminum is detected (not shown).

TABLE 10
The combustion synthesis reaction results by using different reactant
compositions and simultaneously preparing plural batches of the
reaction product with applying the nitrogen gas from the bottom of the
aluminum containers at different conditions.

| | | Thick- | | | |
|---|---|---|---|---|---|
| | Composition | ness | Reactant weight (g) | | |
| | of | of | & Packing density | N₂ | Con- |
| Exp. | initiator | initiator | (g/cm³) for | pressure | version |
| No. | (wt %) | (mm) | each Al container | (atm) | (%) |
| 41 | 50% Al + | 5 mm | 600 g | 2 atm | 99.6% |
| | 50% AlN | | 0.63 g/cm³ | 40 L/min | |
| 42 | 99% Al + | 3 mm | 500 g | 3 atm | 99.5% |
| | 1% NH₄Cl | | 0.6 g/cm³ | 60 L/min | |

In sum, the addition of the diluent, the additive or the aluminum compact according to the present invention can efficiently reduce the melting and coalescence of the aluminum powder and efficiently increase nitrogen gas supply. Furthermore, the reactant doped with aluminum nitride can also reduce the melting and coalescence of the aluminum powder in the bottom and the periphery of the reactant and further improve the flow-in efficiency of nitrogen gas. In addition, the aluminum container with apertures or the aluminum pipe used in the preparation of aluminum nitride according to the present invention can efficiently increase the contact area between nitrogen gas with the reactant to fully complete the reaction. The addition of the initiator also can reduce the thermal-coagulation of aluminum powder on the top of the reactant and shorten the heating time for igniting. Therefore, the method and the apparatus for preparing aluminum nitride according to the present invention have the following advantages:

1. The reaction product, i.e. aluminum nitride, according to the present invention has a higher conversion. That is, the aluminum nitride prepared from the present invention has a higher purity.

2. The present invention can simultaneously prepare plural batches of aluminum nitride, so the aluminum nitride is easily produced on a large scale.

3. The present invention employs the aluminum container instead of the refractory container resisted to the high temperature, so the cost can be reduced.

While the invention has been described in terms of what are presently considered to be the most practical and preferred embodiments, it is to be understood that the invention needs not be limited to the disclose embodiments. On the contrary, it is tented to cover various modification and similar arrangements included within the spirit and scope of the appended claims which are be accorded with the broadest interpretation so as to encompass all such modifications and similar structure.

What is claimed:

1. A method for preparing aluminum nitride (AlN), comprising the steps of:
(a) providing an aluminum container with one open terminal;
(b) providing a reactant to be received in said aluminum container;
(c) placing a layer of an aluminum nitride (AlN) powder between said reactant and said aluminum container;
(d) placing said aluminum container into a reactor with a specific pressure and introducing nitrogen gas into said reactor; and
(e) heating said reactant at a specific temperature till igniting, thereby preparing said aluminum nitride.

2. The method according to claim 1, wherein the side wall structure of said aluminum container is one selected from a group consisting of integral from, single layer with multiple holes, single layer with no holes, multiple layers with multiple holes and multiple layers with no holes.

3. The method according to claim 2, wherein said porous aluminum container having hole diameter ranged from 0.001 to 1.5 mm.

4. The method according claim 3, wherein the total area of said holes is ranged from 1 to 50% of total area of said aluminum container.

5. The method according to claim 1, wherein the thickness of said aluminum container is ranged from 0.01 to 2 mm.

6. The method according to claim 1, wherein said aluminum container has an aluminum content greater than 25 wt %.

7. The method according to claim 1, wherein said reactant is one of an aluminum-containing material and a combination of said aluminum-containing material and a reagent.

8. The method according to claim 7, wherein said aluminum-containing material has an aluminum content greater than 25 wt % and is at least one selected from a group consisting of an pure aluminum powder, an aluminum powder comprising an aluminum alloy, a pure aluminum alloy and other admixture comprising aluminum.

9. The method according to claim 8, wherein said other admixture comprising aluminum is one selected from a group consisting of an aluminum powder mixed with other elements, aluminum fragments produced during the industrial process and fragments of aluminum alloy product.

10. The method according to claim 8, wherein said aluminum-containing material is a pure aluminum powder having a particle size ranged from 0.01 to 200 μm.

11. The method according to claim 7, wherein the packing density of said aluminum-containing is ranged from 0.1 to 1.6 g/cm³.

12. The method according to claim 7, wherein said reagent is one selected from a group consisting of a diluent, an additive and a mixture thereof.

13. The method according to claim 12, wherein said diluent is at least one compound selected from a group consisting of aluminum nitride (AlN) powder, boron nitride (BN) powder, titanium nitride (TiN) powder, silicon carbide (SiC) powder, silicon nitride (Si₃N₄) powder, tungsten carbide (WC) powder, aluminum oxide (Al₂O₃) powder, ferric chloride (FeCl₃) powder, Zirconium dioxide (ZrO₂) powder, titanium dioxide (TiO₂) powder, silicon dioxide (SiO₂) powder, carbon powder and diamond powder.

14. The method according to claim 12, wherein said diluent has a weight ratio of said reactant ranged from 0% to 80%.

15. The method according to claim 12, wherein said additive is at least one selected from a group consisting of an ammonium halide, a compound containing—NHx group and a compound containing halide.

16. The method according to claim 15, wherein said ammonium halides is one selected from a group consisting of ammonium fluoride, ammonium chloride, ammonium bromide and ammonium iodide.

17. The method according to claim 15, wherein said compound containing—NHx group is one selected from a group consisting of CO(NH₂)₂, NH₂CO₂NH₂, (NH₄)₂CO₃, NH₄HF₂, KHF₂, NH₄NO₃, NH₄HCO₃, HCOONH₄, N₂H₄.HCl, N₂H₄.HBr, N₂H₄, N₂H₄.2HCl and a mixture thereof.

18. The method according to claim 15, wherein said a compound containing halide is one selected from a group consisting of aluminum chloride, aluminum bromide, ferric chloride, iodine and a mixture thereof.

19. The method according to claim 12, wherein said additive has a weight ratio of said reactant ranged from 0% to 80%.

20. The method according to claim 1, wherein said step (b) further comprises a step (b1) of placing an initiator on a top surface of said reactant.

21. The method according to claim 20, wherein said initiator is at least one selected from a group consisting of a diluent, an additive, an iodine (I₂) and a mixture which is capable to proceed an exothermic reaction.

22. The method according to claim 21, wherein said mixture is one selected from a group consisting of Ti and C, Al and Fe₃O₄, Al and Fe, and Ni and Al.

23. The method according to claim 21, wherein said mixture has a weight ratio of said initiator ranged from 0.01 to 100 wt %.

24. The method according to claim 21, wherein said initiator has a thickness on the top surface of said reactant ranged from 1 to 30 mm.

25. The method according to claim 1, wherein said layer of said aluminum nitride powder has a thickness ranged from 1 to 100 mm and has a particle size ranged from 0.01 to 10 mm.

26. The method according to claim 1, wherein said specific pressure is ranged from 0.1 to 30 atm.

27. The method according to claim 1, wherein said specific temperature is ranged from 700 to 1700° C.

28. The method according to claim 1, wherein said reactor further comprises a base for placing said aluminum container, and said base is made of one selected from a group consisting of aluminum, graphite, aluminum nitride (AlN), silicon nitride (Si₃N₄), tungsten carbide (WC), aluminum oxide (Al₂O₃), Zirconium dioxide (ZrO₂) and ceramics.

29. A method for simultaneously preparing plural batches of aluminum nitride, comprising the steps of:
(a) providing a plurality of aluminum containers having one open terminal;
(b) providing a plurality of reactants to be received in said aluminum containers respectively;
(c) simultaneously placing said aluminum containers into a reactor with a specific pressure and introducing nitrogen gas into said reactor; and
(d) heating said reactant at a specific temperature till igniting, thereby preparing said aluminum nitride products.

30. An apparatus for preparing an aluminum nitride, comprising:
a reactor resisted to a particular pressure;
a base for placing an aluminum container with one open terminals and a reactant thereon; and
a resistance heating device disposed on said reactant for providing an energy resource, thereby converting said reactant into said aluminum nitride.

31. The apparatus according to claim 28, wherein said reactor comprises:
a thermocouple for measuring a reaction temperature;
a nitrogen gas inlet for providing a nitrogen gas during preparing said aluminum nitride;
a vacuum tube for evacuating air inside said reactor to reach a vacuum status;
a pressure gauge for measuring a pressure during preparing said aluminum nitride; and
a vent for recovering said pressure back to atmospheric pressure after preparing said aluminum nitride.

32. The apparatus according to claim 28, wherein said particular pressure is ranged from 0.1 to 30 atm.
